(19) United States
(12) Patent Application Publication
(10) Pub. No.: US 2025/0379038 A1
(43) Pub. Date: Dec. 11, 2025

(54) PLASMA ETCHING APPARATUS

(71) Applicant: SAMSUNG ELECTRONICS CO., LTD., SUWON-SI (KR)

(72) Inventors: Junghyun SONG, Suwon-si (KR); Songyun KANG, Suwon-si (KR); Kyung-Sun KIM, Suwon-si (KR); Yirop KIM, Suwon-si (KR); Heewon MIN, Suwon-si (KR); Kuihyun YOON, Suwon-si (KR); Insoo LEE, Suwon-si (KR); Junho LEE, Suwon-si (KR); Seungbin LIM, Suwon-si (KR); Minyoung HUR, Suwon-si (KR)

(21) Appl. No.: 18/949,501

(22) Filed: Nov. 15, 2024

(30) Foreign Application Priority Data
Jun. 5, 2024 (KR) 10-2024-0073834

(51) Int. Cl. H01J 37/32

(52) U.S. Cl. CPC H01J 37/3244; H01J 2237/002; H01J 2237/334

(57) ABSTRACT

A plasma etching device includes a chamber receiving a wafer substrate. The wafer substrate is etched inside the chamber. A gas supply device includes a gas box storing a process gas and a gas line transferring the process gas from the gas box to the chamber. A plasma generator generates a plasma from the process gas inside the chamber. A gas cooling device is disposed outside the chamber and cooling the process gas supplied from the gas box to the chamber. The gas line includes an inlet line supplying the process gas from the gas box to the gas cooling device to cool the process gas. An outlet line supplies the cooled process gas from the gas cooling device to the chamber.

### CROSS-REFERENCE TO RELATED APPLICATIONS

This application claims priority under 35 U.S.C. § 119 to Korean Patent Application No. 10-2024-0073834, filed on Jun. 5, 2024 in the Korean Intellectual Property Office, the disclosure of which is incorporated by reference in its entirety herein.

### 1. TECHNICAL FIELD

The present disclosure relates to a plasma etching apparatus.

### 2. DISCUSSION OF RELATED ART

A method of manufacturing a semiconductor device includes performing a series of unit processes including etching, ashing, ion implantation, thin film deposition, cleaning, etc. Among these unit processes, etching may be performed using a plasma etching apparatus in which a plasma reaction is induced.

In the plasma etching apparatus, a bias voltage may be applied to an electrode in a process chamber to control ions activated by the plasma. The bias voltage may be generated by inducing a voltage on the substrate through a wafer chuck. By controlling the induced voltage on the substrate as described above, ion energy incident on the substrate may be precisely controlled. As a result, a structure having a high aspect ratio may be formed using a plasma etching method.

Recently, the stack of semiconductor device has increased to provide a higher integration level and the steps of manufacturing process of the semiconductor device are increasing. Therefore, research is being conducted with respect to attaining a higher etching aspect ratio. For example, to increase the etching aspect ratio, methods such as supplying a higher bias voltage to the plasma etching apparatus are being studied.

### SUMMARY

To solve one or more problems (e.g., the problems described above and/or other problems not explicitly described herein), embodiments of the present disclosure provide a plasma etching apparatus with an increased aspect ratio of an etching process.

Embodiments of the present disclosure also provide a plasma etching apparatus capable of controlling the temperature of process gas.

Embodiments of the present disclosure also provide a plasma etching apparatus that controls the temperature of process gas without causing a change in the temperature of components of the plasma etching apparatus.

According to an embodiment of the present disclosure, a plasma etching apparatus may comprise a chamber receiving a wafer substrate. The wafer substrate is etched inside the chamber. A gas supply device includes a gas box storing a process gas and a gas line transferring the process gas from the gas box to the chamber. A plasma generator generates a plasma from the process gas inside the chamber. A gas cooling device is disposed outside the chamber and cooling the process gas supplied from the gas box to the chamber. The gas line includes an inlet line supplying the process gas from the gas box to the gas cooling device to cool the process gas. An outlet line supplies the cooled process gas from the gas cooling device to the chamber.

According to an embodiment of the present disclosure, a plasma etching apparatus includes a chamber for a plasma etching process. An electrostatic chuck fixes a wafer substrate in the chamber to etch the wafer substrate. A gas supply device includes a gas box storing a process gas and a gas line supplying the process gas from the gas box into the chamber. A plasma generator generates a plasma from the process gas inside the chamber. A gas cooling device is coupled to the gas line from outside the chamber. The gas cooling device includes a gas flow path that the process gas passes through and a cooling flow path that a coolant passes through. A chiller supplies the coolant to the cooling flow path to cool the process gas passing through the gas flow path. The gas cooling device further includes a temperature sensor measuring a temperature of the process gas flowing inside the gas line or the gas flow path. A control unit controls the chiller to adjust a temperature of the coolant based on the temperature of the process gas measured by the temperature sensor.

According to an embodiment of the present disclosure, a plasma etching apparatus includes a chamber for a plasma etching process. A support includes an electrostatic chuck fixing a wafer substrate inside the chamber. A gas box stores a process gas. A gas injection unit injects the process gas into the chamber. The gas injection unit includes a first gas injection unit disposed above the wafer substrate, and a second gas injection unit disposed on a sidewall of the chamber. An inductively coupled plasma generator generates a plasma from the process gas injected by the gas injection unit. A gas line is connected to supply the process gas from the gas box into the chamber. A bypass line directly connects the gas box and the chamber to each other. A gas cooling device includes a gas flow path that the process gas flowing through the gas line passes through. The gas cooling device is disposed outside the chamber. A chiller includes a first channel supplying a coolant to the wafer substrate and a second channel supplying the coolant to the gas cooling device. A temperature sensor is disposed on the gas line and the gas flow path. The temperature sensor measures a temperature of the process gas. A pressure sensor is disposed on the gas line and the gas flow path. The pressure sensor measures a pressure of the process gas. A control unit controls the chiller based on the temperature of the process gas measured by the temperature sensor or the pressure of the process gas measured by the pressure sensor.

According to some aspects of embodiments of the present disclosure, it is possible to increase the aspect ratio by increasing ion straightness through the temperature control of the process gas, while maintaining the homeostasis of the etching process of the plasma etching apparatus.

According to some aspects of embodiments of the present disclosure, it is possible to independently adjust the temperature of the process gas to increase ion straightness, while maintaining the temperatures of the chamber main body and parts constant to maintain the homeostasis of the etching process of the plasma etching apparatus.

The effects of embodiments of the present disclosure are not limited to the effects described above, and other effects not described herein can be clearly understood by those of ordinary skill in the art (referred to as “ordinary technician”) from the description of the claims.

### BRIEF DESCRIPTION OF THE DRAWINGS

FIG. 1 is a perspective view of a plasma etching apparatus according to an embodiment of the present disclosure.

FIG. 2 is a schematic view illustrating a configuration of a plasma etching apparatus according to an embodiment of the present disclosure.

FIG. 3 is a diagram provided to explain a plasma etching apparatus according to an embodiment of the present disclosure.

FIG. 4 is an exploded view illustrating a gas cooling device according to an embodiment of the present disclosure.

FIG. 5 is a front view of a gas cooling device according to an embodiment of the present disclosure.

FIG. 6 is an exploded view illustrating a part of a gas cooling device according to an embodiment of the present disclosure.

FIG. 7 is a diagram illustrating a gas flow path and a cooling flow path of the gas cooling device according to an embodiment of the present disclosure.

FIG. 8 is a schematic diagram illustrating a movement pattern of ions inside the plasma etching apparatus according to an embodiment of the present disclosure.

FIG. 9 is a diagram illustrating an etching pattern of a wafer by ions generated by the plasma etching apparatus of FIG. 8 according to an embodiment of the present disclosure.

FIG. 10 is a graph illustrating an arrival rate of ions according to temperature of process gas according to an embodiment of the present disclosure.

FIG. 11 is a block diagram illustrating a configuration of a plasma etching apparatus for controlling a temperature of a process gas according to some aspects according to an embodiment of the present disclosure.

FIGS. 12 to 15 are flowcharts provided to explain a method for controlling the temperature of the process gas of the gas cooling device according to some embodiments of the present disclosure.

### DETAILED DESCRIPTION OF EMBODIMENTS

Hereinafter, a plasma processing apparatus according to some embodiments of the present disclosure will be described in detail with reference to the drawings. However, in the following description, detailed descriptions of well-known functions or configurations may be omitted for economy of explanation.

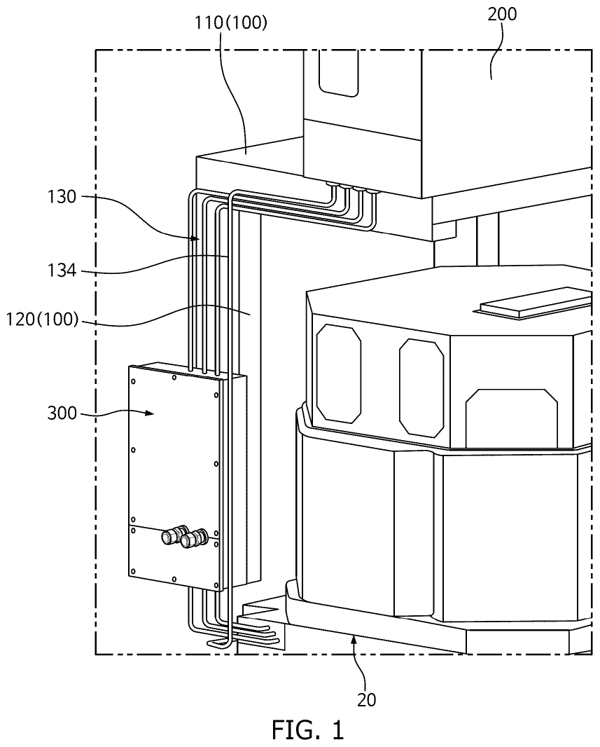

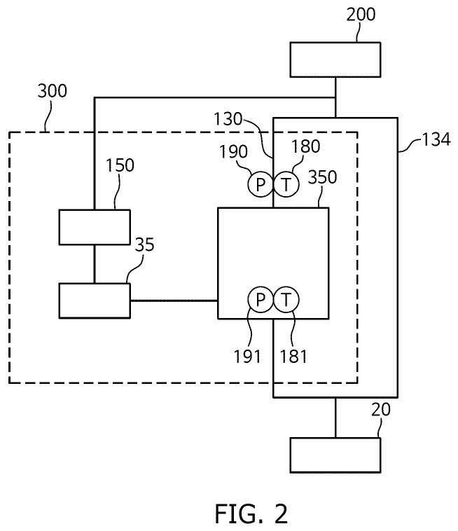

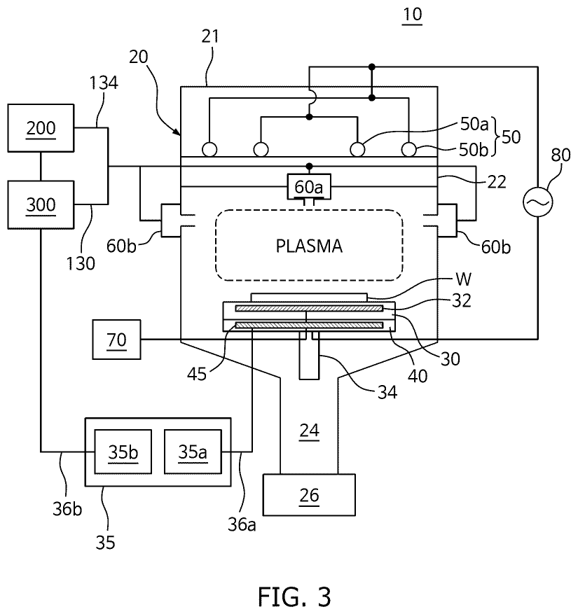

FIG. 1 is a perspective view of a plasma etching apparatus according to some aspects. FIG. 2 is a schematic view illustrating a configuration of a plasma etching apparatus according to some aspects. FIG. 3 is a diagram provided to explain a plasma etching apparatus according to some aspects.

Referring to FIGS. 1 to 3, the plasma etching apparatus may include a chamber 20 for etching a wafer substrate W, a gas supply device, a plasma generator 80, and a gas cooling device 300. In an embodiment, the gas supply device may include a gas box 200 that stores process gas, and a gas line 130 and a bypass line 134 formed to transfer the process gas from the gas box 200 to the chamber 20. The gas cooling device 300 may be disposed outside the chamber 20.

In addition, the gas cooling device 300 may be provided on the path of the gas line 130 to cool the process gas moving through the gas line 130. As described above, since the gas cooling device 300 is disposed outside the chamber 20, at least a portion of the process gas supplied from the gas box 200 to the chamber 20 may be cooled without causing a change in the temperature of the components of the chamber 20.

Referring to FIG. 1, a support frame 100 may be provided to support the gas box 200 and the gas line 130 disposed above the chamber 20 in the plasma etching apparatus. In an embodiment, the support frame 100 may include a base portion 110 that supports the gas box 200, and a support portion 120 that extends along the gas line 130. The gas box 200 may be disposed on the base portion 110. In an embodiment, the gas box 200 may be disposed above the chamber 20. However, the position of the gas box 200 is not necessarily limited thereto. The support portion 120 may extend downward from the base portion 110 to support the base portion 110. In an embodiment in which the gas box 200 is disposed above the chamber 20, the support portion 120 may extend higher than the chamber 20 such that the base portion 110 is disposed above the chamber 20.

The gas line 130 may connect the gas box 200 and the chamber 20 to each other. The gas line 130 may extend along the support portion 120. In an embodiment in which the gas box 200 is positioned higher than the chamber 20, the gas line 130 may extend downward along side surfaces of the base portion 110 and the support portion 120 supporting the gas box 200. In an embodiment, the gas line 130 may be fixed to the side surface of the support portion 120 in an area in which the gas line 130 extends along the support portion 120. In addition, the gas line 130 may be bent in a portion of an area in which the gas line 130 extends along the side surfaces of the base portion 110 and the support portion 120. However, embodiments of the present disclosure are not necessarily limited thereto, and the gas line 130 may be arranged in various shapes to connect the gas box 200 and the chamber 20 to each other.

Plasma may be generated in the chamber 20 to etch the wafer substrate W. Inside the chamber 20, etching may be performed on a target structure (e.g., on a wafer substrate) using the generated plasma. In an embodiment, the plasma etching may be performed by applying high energy to gaseous molecules in a vacuum so that the molecules are ionized or decomposed to be activated, and the collision of the activated particles with the thin film breaks the crystal structure of the thin film, thus removing the thin film.

A support 30 may be provided inside the chamber 20. The wafer substrate W may be disposed on the support 30. In an embodiment, the support 30 may be a susceptor for supporting the wafer substrate W. For example, in an embodiment the support 30 may be an electrostatic chuck (ESC) for maintaining the substrate W located on an upper portion thereof with electrostatic adsorption power. However, embodiments of the present disclosure are not necessarily limited thereto. The electrostatic chuck may fix the wafer substrate W to etch the wafer substrate W. For example, the electrostatic chuck may adsorb and maintain the wafer substrate W with constant power by the direct current voltage supplied from a direct current power source 70.

The chamber 20 may provide an internal space to receive the wafer substrate W and have a plasma processing performed on the wafer substrate W supported by the support 30. The inner space of the chamber 20 may be in a closed state. Plasma for semiconductor process may be formed in the inner space of the chamber 20, and the space in which the plasma is formed may be referred to as a “plasma region”.

In an embodiment, the chamber 20 may include an exhaust port 24 and an exhaust part 26 for maintaining the internal space of the chamber 20 in a vacuum state or adjusting to a desired pressure. The exhaust part 26 may be connected to the exhaust port 24 provided below the chamber 20. In an embodiment, the exhaust part 26 may include a vacuum pump such as a turbo molecular pump to adjust the degree of vacuum of the space inside the chamber 20 to a required level. In addition, process by-products and residual process gases generated in the chamber 20 may be discharged through the exhaust port 24.

In an embodiment, the plasma etching apparatus may be an inductively coupled plasma (ICP) etching apparatus. The plasma etching apparatus may be an apparatus for etching an etching target film on the wafer substrate W disposed in the chamber 20. However, the plasma etching apparatus is not necessarily limited to the inductively coupled plasma etching apparatus. For example, the plasma etching apparatus may be a capacitively coupled plasma etching apparatus or a microwave-type plasma etching apparatus in some embodiments. In addition, the apparatus illustrated herein is not necessarily limited to the etching apparatus, and may be used, for example, as a deposition apparatus, a cleaning apparatus, etc. For example, instead of the wafer substrate W, a semiconductor substrate, a glass substrate, etc. may be processed in the apparatus.

The plasma etching apparatus may include the plasma generator 80 that generates plasma from the process gas inside the chamber 20. The plasma generator 80 may be connected to an upper electrode 50 and a lower electrode 40. High frequency power may be applied to the upper electrode 50 and the lower electrode 40 using the power supplied from the plasma generator 80. In an embodiment, the plasma generator 80 may provide bias power having a pulsed sinusoidal waveform to the lower electrode 40 using a pulse signal, or may provide source power having a high frequency waveform to the upper electrode 50. As shown in FIG. 3, the lower electrode 40 may be disposed inside the support 30, and the upper electrode 50 may be disposed above the chamber 20. In an embodiment, the lower electrode 40 may be connected to a bias power supply unit, and the upper electrode 50 may be connected to a source power supply unit.

In an embodiment, the support 30 may include a disk-shaped lower electrode 40 under the electrostatic chuck. The lower electrode 40 may be movably provided to be moved up and down by a driving unit 34. In an embodiment, the wafer substrate W may be mounted on an upper side of the support 30, and a focus ring may be mounted around the wafer substrate W. In an embodiment, the lower electrode 40 may have a diameter larger than that of the wafer substrate W. The support 30 may further include a heater 32 for controlling the temperature of the wafer substrate W or the support 30. Heat generated by the heater 32 may be transferred to the wafer substrate W, and the wafer substrate W may be maintained at a predetermined temperature.

In an embodiment, the plasma etching apparatus may further include a chiller 35 for cooling the wafer substrate W and/or the process gas. In an embodiment, the chiller 35 may include a first chiller 35a for supplying coolant to the wafer substrate W inside the chamber 20, and a second chiller 35b for supplying coolant to the gas cooling device 300 to be described below.

In an embodiment, the first chiller 35a may be connected to a circulation channel 45 formed in the lower electrode 40. The first chiller 35a may include a first channel 36a for supplying coolant to the wafer substrate W. For example, the first channel 36a may be connected to supply the coolant to the circulation channel 45. The chiller 35 may supply the coolant between the electrostatic chuck and the wafer substrate W to control the temperature of the wafer substrate W. The coolant may circulate through the circulation channel 45 to cool the wafer substrate W. For example, in an embodiment the coolant may be helium (He) gas. However, embodiments of the present disclosure are not necessarily limited thereto.

The second chiller 35b may be connected to the gas cooling device 300. In an embodiment, the second chiller 35b may include a second channel 36b for supplying the coolant to the gas cooling device 300. The coolant may be supplied to the gas cooling device 300 to cool the process gas passing through the gas cooling device 300. In an embodiment, the second chiller 35b may adjust the temperature of the coolant to be in a range less than or equal to about 40 degrees Celsius and supply the coolant to the gas cooling device 300.

An antenna room 21 may be formed above the chamber 20. In addition, an antenna window 22 may be provided to close the antenna room 21. The upper electrode 50 may be disposed inside the antenna room 21. In an embodiment, the upper electrode 50 may be disposed in the antenna room 21 to face the lower electrode 40. The upper electrode 50 may be disposed on the antenna window 22. In an embodiment, the upper electrode 50 may include a high frequency (RF) antenna. The antenna may have a planar coil shape. The antenna window 22 may include a disk-shaped dielectric material. For example, in an embodiment the antenna window 22 may include aluminum oxide (Al₂O₃). The antenna window 22 may transfer power from the upper electrode 50 to the inside of the chamber 20.

In an embodiment, the upper electrode 50 may include an inner coil 50a and an outer coil 50b. The inner coil 50a and the outer coil 50b may have a spiral shape or a concentric shape. The inner coil 50a and the outer coil 50b may generate inductively coupled plasma in the plasma region of the chamber 20. Two coils have been illustrated in an embodiment shown in FIG. 3. However, the number and arrangement of coils are not necessarily limited thereto and may vary.

In the gas supply device for supplying the process gas into the chamber 20, the gas cooling device 300 may cool the process gas supplied from the gas box 200. The process gas may include an etching material, an additive gas, an inert gas, etc. For example, in an embodiment the process gas may include at least one of O₂, He, Ar, C₄F₈, C₄F₆, ClF₃, BCl₃, WF₆, HF, Cl₂, NF₃, HBr, CHF₃, SF₆, or a combination thereof.

In an embodiment, at least one of the gas line 130 and the bypass line 134 formed to transfer the process gas from the gas box 200 may be connected to gas injection units 60a and 60b that inject the process gas into the chamber 20.

The gas line 130 and the bypass line 134 may connect the gas box 200 and the chamber 20. In an embodiment, the gas line 130 may connect the gas box 200 and the chamber 20 through the gas cooling device 300. The bypass line 134 may directly connect the gas box 200 and the chamber 20 from outside the gas cooling device 300. For example, the bypass line 134 may bypass the gas cooling device and directly connect the gas box 200 and the chamber 20.

The process gas supplied from the gas box 200 may be supplied into the chamber 20 through the gas line 130 or the bypass line 134. The process gas moving through the gas line 130 may pass through the gas cooling device 300. The process gas moving through the bypass line 134 may be directly supplied to the chamber 20 without passing through the gas cooling device 300. For example, the process gas moving through the gas line 130 may be cooled by the gas cooling device 300, and the process gas moving through the bypass line 134 may not be cooled by the gas cooling device 300.

In an embodiment, the gas injection units may include the first gas injection unit 60a and the second gas injection unit 60b, respectively. The first gas injection unit 60a may supply the process gas to an upper portion of the chamber 20, and the second gas injection unit 60b may supply the process gas from a sidewall of the chamber 20. For example, in an embodiment as shown in FIG. 3, the second gas injection unit 60b may include two units supplying the process gas to opposing sidewalls of the chamber 20. However, embodiments of the present disclosure are not necessarily limited thereto. The first gas injection unit 60a may penetrate the antenna window 22. For example, the first gas injection unit 60a may be disposed above the wafer substrate W. The first gas injection unit 60a may inject the process gas towards the center of the wafer substrate W.

The second gas injection unit 60b may be disposed on the sidewall of the chamber 20. The second gas injection unit 60b may penetrate the sidewall of the chamber 20. The second gas injection unit 60b may inject the process gas towards a peripheral region of the wafer substrate W. The gas injection units 60a and 60b may supply various gases to the plasma region in the chamber 20.

The gas supply device may supply different process gases at a desired ratio. In an embodiment, the gas box 200 stores a plurality of gases, and the process gases may be supplied through the gas line 130 and/or the bypass line 134 connected to the gas injection units 60a and 60b, respectively.

Referring to FIG. 2, in an embodiment the gas cooling device 300 may include the chiller 35, a gas cooling unit 350, temperature sensors 180 and 181, pressure sensors 190 and 191, and a control unit 150.

The temperature sensors 180 and 181 may measure the temperature of the process gas flowing into the gas line 130 and the gas cooling unit 350. The pressure sensors 190 and 191 may measure the pressure of the process gas flowing into the gas line 130. The control unit 150 may control the temperature of the process gas based on the temperature of the process gas measured by the temperature sensors 180 and 181 and/or the pressure sensors 190 and 191. For example, in an embodiment the control unit 150 may control the chiller 35 based on the temperature of the process gas measured by the temperature sensors 180 and 181 and/or the pressure sensors 190 and 191 so as to adjust the temperature of the coolant circulating in the gas cooling unit 350 and thus adjust the temperature of the process gas passing through the gas cooling unit 350.

In an embodiment, the temperature sensors 180 and 181 may include a first temperature sensor 180 disposed upstream of the gas cooling unit 350, and a second temperature sensor 181 disposed inside the gas cooling unit 350. The control unit 150 may determine whether to pass the process gas discharged from the gas box 200 to the gas cooling device 300 based on the temperature of the process gas measured by the first temperature sensor 180. The control unit 150 may feedback control the temperature of the process gas passing through the gas cooling unit 350 based on the temperature of the cooled process gas in the gas cooling device 300 measured by the second temperature sensor 181.

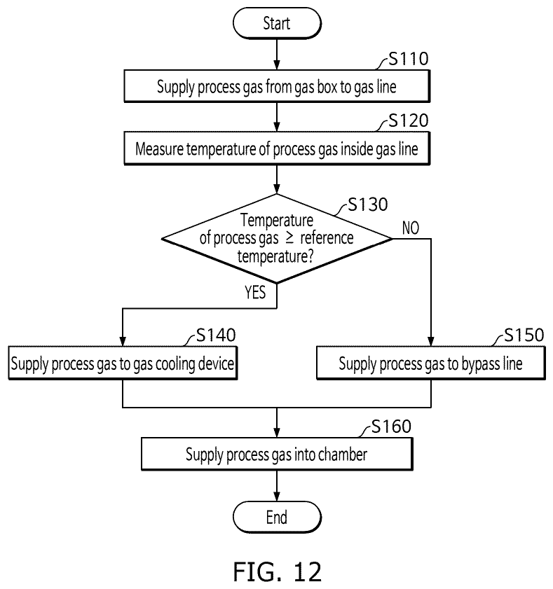

In an embodiment, the pressure sensors may include the first pressure sensor 190 disposed upstream of the gas cooling unit 350, and the second pressure sensor 191 disposed downstream of the gas cooling unit 350. In an embodiment, the control unit 150 may control the gas cooling unit 350 to prevent liquefaction of the process gas based on the pressure of the process gas measured by the first pressure sensor 190. For example, the control unit 150 may adjust the temperature of the process gas based on the pressure of the cooled process gas in the gas cooling device 300 measured by the second pressure sensor 181. A method for controlling the temperature of the process gas using the gas cooling device 300 will be described in detail with reference to FIGS. 12 to 15.

The gas cooling device 300 may be disposed outside the chamber 20. The gas line 130 may be coupled to the gas cooling device 300 from outside the chamber 20. Since the gas cooling device 300 is disposed outside the chamber 20, the process gas may be cooled without causing a change in the temperature of the components of the chamber 20. It may be desirable that the temperature of the components of the chamber 20 does not change to maintain a constant process performance of the components. In addition, to use the chamber 20 in various processes of manufacturing semiconductors, it is necessary to keep the temperature of each of the components constant. In an embodiment, the plasma etching apparatus may cool the temperature of the process gas without causing a change in the temperature of the components of the chamber 20.

In an embodiment, the plasma etching apparatus may include the chamber 20 for etching the wafer substrate W, the gas box 200 that stores the process gas, the gas supply device including the gas line 130 formed to transfer the process gas from the gas box 200 to the chamber 20, the plasma generator 80 that generates plasma from the process gas inside the chamber 20, and the gas cooling device 300 that is disposed outside the chamber 20 and that cools the process gas supplied from the gas box 200.

In an embodiment, the gas line 130 may include an inlet line that supplies the process gas from the gas box 200 to the gas cooling device 300 to cool the process gas, and an outlet line that supplies the process gas cooled in the gas cooling device 300 to the chamber 20.

Hereinafter, the configuration and structure of the gas cooling device 300 and the gas line 130 connected to the gas cooling device 300 will be described.

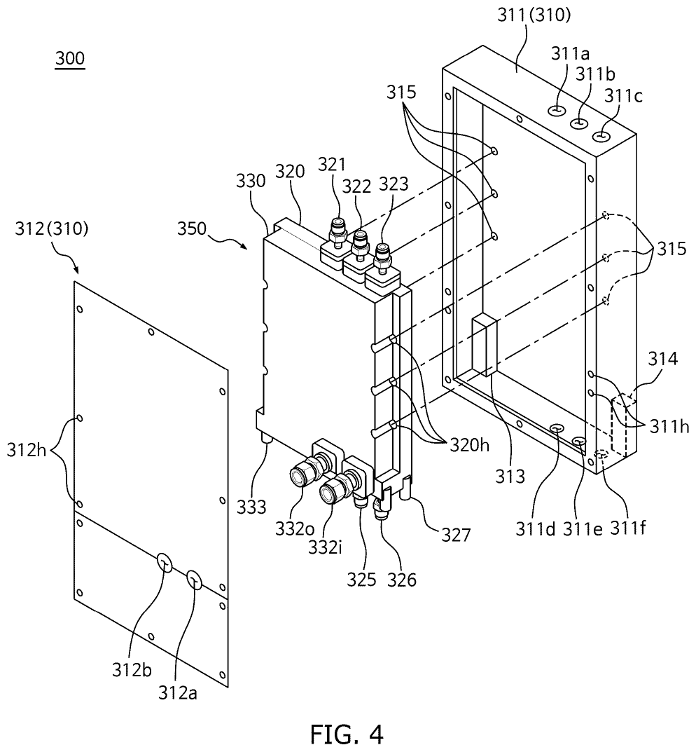

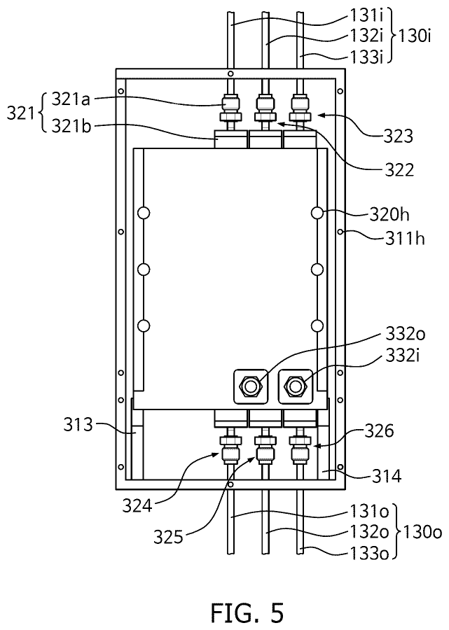

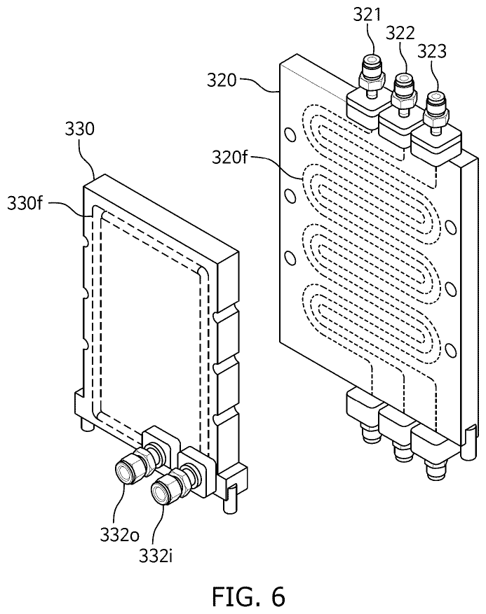

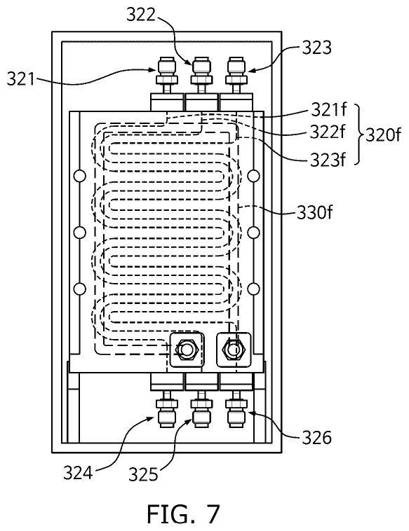

FIG. 4 is an exploded view illustrating a gas cooling device according to some aspects. FIG. 5 is a front view of a gas cooling device according to some aspects. FIG. 6 is an exploded view illustrating a part of a gas cooling device according to some aspects. FIG. 7 is a diagram illustrating a gas flow path and a cooling flow path of the gas cooling device.

Referring to FIGS. 4 to 6, in an embodiment the gas cooling device 300 may include the gas cooling unit 350, and a cabinet 310 accommodating the gas cooling unit 350 therein. In an embodiment, as shown in FIG. 4 the cabinet 310 may be a rectangular parallelepiped shape. However, embodiments of the present disclosure are not necessarily limited thereto.

The cabinet 310 may include a cabinet body 311 defining a space for accommodating the gas cooling unit 350, and a cabinet cover 312 that covers the cabinet body 311. The cabinet 310 may be coupled to the support frame 100 (see FIG. 1). In an embodiment, the cabinet 310 may be fastened to the support frame 100 by a fastening member such as a bolt. However, embodiments of the present disclosure are not necessarily limited thereto. The cabinet body 311 may include a fastening hole 315 to be fastened with the support frame 100.

The cabinet 310 may be formed of a material having a relatively high strength. In an embodiment, the cabinet 310 may include a metallic material. For example, the cabinet 310 may include steel plate cold commercial (SPCC) metal. However, the material of the cabinet 310 is not necessarily limited to the above, and may include various materials having appropriate strength.

In an embodiment, the cabinet body 311 may include support bars 313 and 314 supporting the gas cooling unit 350. The support bars 313 and 314 may support the gas cooling unit 350 while the gas cooling unit 350 is accommodated in the cabinet body 311. In an embodiment, a portion of the gas cooling unit 350 supported by the support bars 313 and 314 may include engineering plastic for insulation.

In an embodiment, the cabinet body 311 may include inlet line holes 311a, 311b, and 311c through which an inlet line 130i passes, and outlet line holes 311d, 311e, and 311f through which an outlet line 1300 passes. The inlet line holes 311a, 311b, and 311c may be formed in an upper portion of the cabinet body 311, and the outlet line holes 311d, 311e, and 311f may be formed in a lower portion of the cabinet body 311. In an embodiment shown in FIG. 4, it is illustrated that there are three inlet line holes 311a, 311b, and 311c and three outlet line holes 311d, 311e, and 311f, respectively. However, embodiments of the present disclosure are not necessarily limited thereto and the number of inlet line holes 311a, 311b, and 311c and outlet line holes 311d, 311e, and 311f may vary, such as depending on the number of inlet lines 130i and outlet lines 1300.

In an embodiment, the cabinet cover 312 may include a fastening hole 312h to be fastened with the cabinet body 311. The fastening hole 312h may be formed along a circumference of the cabinet cover 312. In addition, a fastening hole 311h may be formed at a position corresponding to the fastening hole 312h along the circumference of the cabinet body 311.

In an embodiment, the cabinet cover 312 may include the inlet hole 312a through which a coolant inlet 332i passes, and the outlet hole 312b through which a coolant outlet 332o passes. The inlet hole 312a and the outlet hole 312b may be formed on a front side of the gas cooling unit 350.

The gas cooling unit 350 may be coupled to the cabinet body 311. For example, in an embodiment the gas cooling unit 350 may be fastened to the cabinet body 311 through a bolt, etc. The gas cooling unit 350 may include a fastening hole 320h for fastening with the cabinet body 311. The fastening hole 315 may be formed in the cabinet body 311 to correspond to the fastening hole 320h of the gas cooling unit 350.

The gas cooling unit 350 may be fastened to the cabinet body 311 and the support frame 100 (see FIG. 1). For example, fastening members such as bolts may pass through the fastening hole 320h of the gas cooling unit 350 and the fastening hole 315 of the cabinet body 311 and be fastened to the support frame 100.

Referring to FIGS. 5 to 7, the gas cooling unit 350 may include a gas case 320 that is connected to the gas line 130 and that has a gas flow path 320f formed to allow the process gas to flow. The gas line 130 may include the inlet line 130i and the outlet line 130o. For example, in an embodiment the gas line 130 may include the inlet line 130i located upstream of the gas cooling device 300 and the outlet line 1300 located downstream of the gas cooling device 300.

The gas case 320 may include inlet ports 321, 322, and 323. The inlet ports 321, 322, and 323 may be connected to the inlet line 130i. The process gas moving through the inlet line 130i may be introduced into the gas flow path 320f through the inlet ports 321, 322, and 323.

In an embodiment, the gas case 320 may include outlet ports 324, 325, and 326. The outlet ports 324, 325, and 326 may be connected to the outlet line 1300. The process gas introduced through the inlet line 130i may pass through the gas flow path 320f and flow out to the outlet line 130o through the outlet ports 324, 325, and 326.

In an embodiment, the inlet ports 321, 322, and 323 and the outlet ports 324, 325, and 326 may correspond to each other on a one-to-one basis. In addition, in an embodiment the gas flow path 320f may include independent flow paths corresponding in number to the inlet ports 321, 322, and 323 or to the outlet ports 324, 325, and 326. For example, in an embodiment a first inlet port 321 and a first outlet port 324 may be connected to a first inlet line 131i and a first outlet line 131o, respectively. A second inlet port 322 and a second outlet port 325 may be connected to a second inlet line 132i and a second outlet line 132o, respectively. A third inlet port 323 and a third outlet port 326 may be connected to a third inlet line 133i and a third outlet line 133o, respectively.

The first inlet line 131i and the first outlet line 131o may be referred to as a first gas line 131, the second inlet line 132i and the second outlet line 132o may be referred to as a second gas line 132, and the third inlet line 133i and the third outlet line 133o may be referred to as a third gas line 133, respectively. The first to third gas lines 131, 132, and 133 may be connected to the chamber 20 to inject the process gas toward different positions within the chamber 20. For example, in an embodiment the first gas line 131 may supply the process gas to the first gas injection unit 60a (see FIG. 3), and the second gas line 132 and the third gas line 133 may supply the process gas to the second gas injection unit 60b (see FIG. 3). However, this is merely an example and embodiments of the present disclosure are not necessarily limited thereto.

In an embodiment, the gas flow path 320f may include a first gas flow path 321f connecting the first inlet port 321 and the first outlet port 324, a second gas flow path 322f connecting the second inlet port 322 and the second outlet port 325, and a third gas flow path 323f connecting the third inlet port 323 and the third outlet port 326.

The inlet ports 321, 322, and 323 and the outlet ports 324, 325, and 326 may include a connection part and a nozzle part, respectively. For example, in an embodiment the first inlet port 321 may include a first inlet nozzle part 321a and a first inlet connection part 321b. The first inlet line 131i may be connected to the first inlet nozzle part 321a. The first inlet connection part 321b may include an insulating material. For example, in an embodiment the first inlet connection part 321b may include an engineering plastic. The description of the first inlet port 321 may be equally applicable to the second and third inlet ports 322 and 323, and the first to third outlet ports 324, 325, and 326 and a repeated description may be omitted for economy of explanation.

The gas cooling unit 350 may include a cooling case 330 coupled to one side of the gas case 320. The cooling case 330 may include a cooling flow path 330f through which the coolant flows to exchange heat with the process gas flowing through the gas flow path 320f.

The chiller 35 may supply the coolant to the cooling flow path 330f. For example, in an embodiment the second chiller 35b may supply the coolant to the cooling flow path 330f through the second channel 36b. However, embodiments of the present disclosure are not necessarily limited thereto, and the first channel 36a and the second channel 36b may be branched off from one chiller 35 to supply the coolant to the circulation channel 45 in the chamber 20 and the cooling flow path 330f of the gas cooling device 300 outside the chamber 20, respectively.

Referring to FIG. 7, in an embodiment the gas flow path 320f may be arranged to have a shape that is repeatedly bent inside the gas case 320. Since the gas flow path 320f has a shape that is repeatedly bent, a distance and a time for the process gas to move in the gas case 320 may increase. Therefore, the process gas passing through the gas flow path 320f may exchange heat with the coolant passing through the cooling flow path 330f for an increased time.

The coolant may flow along the cooling flow path 330f. The coolant may flow into the cooling flow path 330f through the coolant inlet 332i, and flow into the chiller 35 (see FIG. 3) through the coolant outlet 3320. The chiller 35 may cool the coolant after a heat exchange back to the initial state. The coolant may circulate between the chiller 35 and the cooling case 330.

The cooling flow path 330f may cool the cooling case 330. In an embodiment, the cooling case 330 may be coupled to the front side of the gas case 320. The cooling case 330 and the gas case 320 may be coupled in such a direction that the heat exchange efficiency can increase. Each of the cooling case 330 and the gas case 320 may be disposed in such a direction that the cooling flow path 330f and the gas flow path 320f overlap each other.

In an embodiment, the cooling case 330 and the gas case 320 may include a metal material having high thermal conductivity. For example, in an embodiment the cooling case 330 and the gas case 320 may include stainless steel such as SUS316. In an embodiment, the cooling case 330 and the gas case 320 may be coupled to each other through welding.

In an embodiment, condensation prevention technology may be applied to the gas case 320 and the cooling case 330 to prevent condensation during heat exchange. For example, in an embodiment compressed dry air may be supplied to the gas cooling unit 350 in accordance with the Clean Dry Air (CDA) standard to prevent condensation.

In an embodiment, the cooling case 330 may be cooled close to the temperature of the coolant passing through the cooling flow path 330f. For example, the temperature of the cooling case 330 may be lowered to be approximate to the temperature of the coolant. In an embodiment, the gas case 320 may be in direct contact with the cooling case 330. The process gas passing through the gas flow path 320f inside the gas case 320 may lose heat to the cooling case 330. Accordingly, the temperature of the process gas passing through the gas flow path 320f may decrease towards the temperature of the cooling case 330. As described above, the temperature of the process gas passing through the gas flow path 320f may be adjusted by controlling the temperature of the coolant passing through the cooling flow path 330f.

The relationship between the temperature of the process gas and the etching aspect ratio will be described.

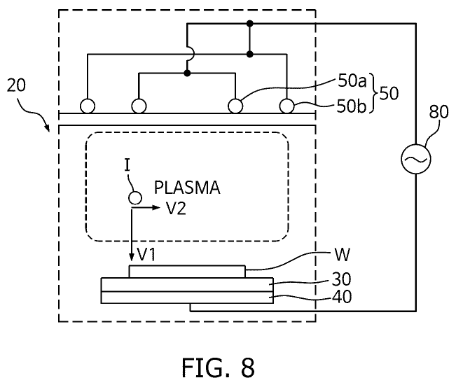

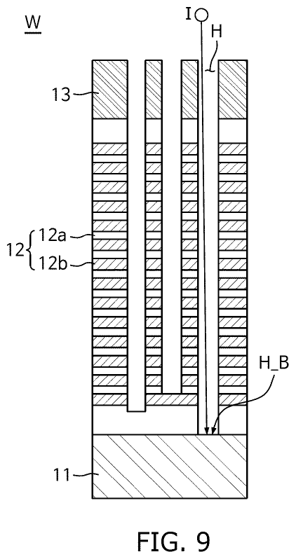

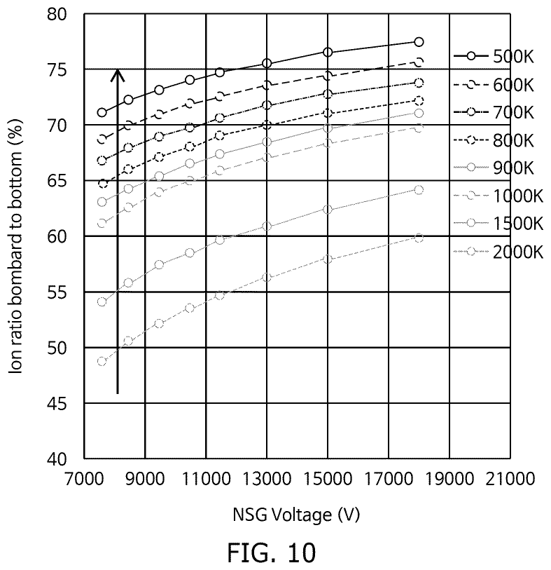

FIG. 8 is a schematic diagram illustrating a movement pattern of ions inside the plasma etching apparatus. FIG. 9 is a diagram illustrating an etching pattern of a wafer by ions generated by the plasma etching apparatus of FIG. 8. FIG. 10 is a graph illustrating an arrival rate of ions according to temperature of process gas.

The plasma etching apparatus according to an embodiment may etch the wafer substrate W using plasma. Ions I may be present in a plasma region formed inside the chamber 20 of the plasma etching apparatus. The ions I in the plasma region may be incident on the wafer substrate W to etch the wafer substrate W.

In an embodiment, the straightness of the ions I may be increased in the direction perpendicular to the surface of the wafer substrate W to increase the etching aspect ratio of the wafer substrate W. In an embodiment, the plasma generator 80 may apply a higher bias power to increase the straightness of the ions I. However, the higher the applied bias power, the more it is likely that arcing would occur in the metal part of the wafer substrate W and/or the support 30.

The plasma etching apparatus according to some aspects may lower the temperature of the process gas to increase the straightness of ions. When plasma is generated inside the chamber 20, the temperature of the ions I may be determined by collision with electrons or neutral particles in the plasma. Since the mass of electrons is negligibly small compared to the mass of the ions I, the temperature of the ions I may be determined by the collision with neutral particles. Thus, the temperature of the neutral particles (e.g., the temperature of the process gas) may affect the temperature of the ions I.

The ions I may have its own kinetic energy due to temperature. The kinetic energy of the ions I may be proportional to the temperature. For example, the temperature of the ions may be determined by a vertical velocity V1 and a horizontal velocity V2 of the ions I. The vertical velocity V1 of the ions I may vary according to an electric field by bias power. Additionally, the horizontal velocity V2 of the ions I may be affected by the temperature of the ions I. For example, if the temperature of the ions I decreases, the horizontal velocity V2 of the ions I may decrease, and the straightness of the ions I in the vertical direction may be increased

Referring to FIG. 9, the ions I may be incident on the wafer substrate W.

For example, in an embodiment the wafer substrate W may include, on a lower substrate 11, sacrificial layers 12a and interlayer insulating layers 12b alternately stacked on top of each other (e.g., in a vertical direction). The sacrificial layer 12a and the interlayer insulating layer 12b may be referred to as a mold layer 12. In an embodiment, the lower substrate 11 may be formed of silicon, and the sacrificial layer 12a may be formed of a material that can be etched with etching selectivity with respect to the interlayer insulating layer 12b. For example, in an embodiment the interlayer insulating layer 12b may be formed of at least one of silicon oxide and silicon nitride, and the sacrificial layer 12a may be formed of a material different from the interlayer insulating layer 12b selected from silicon, silicon oxide, silicon carbide, and silicon nitride.

A mask layer 13 may be stacked over the wafer substrate W. In an embodiment, the mask layer 13 may be a layer formed of a carbon-containing material such as an amorphous carbon layer (ACL) or a spin-on hardmask (SOH). Note that the illustrated structure of the wafer substrate W is merely an example, and embodiments of the present disclosure are not necessarily limited thereto. For example, the substrate W may further include a structure other than the lower substrate 11, the mold layer 12, and the mask layer 13, and each configuration may be formed of various materials.

If the initial etching process for the mask layer 13 is completed, the plasma etching apparatus may perform etching on the mold layer 12. The step of performing etching on the mold layer 12 may be defined as a main etching step. In an embodiment, the main etching step of the plasma etching process may be performed as a low-temperature process to increase an etching rate. This low-temperature process may be implemented by reducing the temperature of the process gas used in the plasma etching process. For example, the low temperature process may be performed using the gas cooling device of the plasma etching apparatus described above with reference to FIGS. 1 to 8. If the process is performed at a low temperature, the reaction of the etching gas with respect to the etching target may increase, thereby increasing the etching rate.

In the main etching step, a plurality of holes H may be formed at a high aspect ratio with a relatively narrow width. As the number of mold layers 12 in the stack is increased for integration of semiconductor device, the height of the mold layer 12 may gradually increase. To manufacture a structure having such a high aspect ratio, the straightness of the ions I incident on the wafer substrate W may be increased by implementing a low-temperature process.

For example, in an embodiment, a plurality of holes H of FIG. 9 may be etched to achieve an aspect ratio of 300:1. For example, to achieve the aspect ratio of 300:1, the ratio of the vertical velocity V1 and the horizontal velocity V2 of the ions I reaching the wafer substrate W may be 300:1. The energy of the ions I may be proportional to the square of the velocity of the ions I. Accordingly, the ratio of the vertical energy to the horizontal energy of the ions I may be 90,000:1. If the horizontal energy of the ions I is 0.1 eV, the vertical energy of 9000 eV of the ions I may be required. To increase the etching aspect ratio, it may be more advantageous if the incident angle of the ions I is close to vertical. For example, in an embodiment, to maintain the etching aspect ratio of 300:1, the ratio of the vertical velocity VI to the horizontal velocity V2 of the ions I may be set to 300:1.

If the temperature of the ions I is reduced by half, such as if the horizontal velocity V2 of the ions I is reduced by half, in terms of the incident angle of the ions I, it is possible to obtain the same effect as doubling the vertical velocity V1 of the ions I. Since the vertical velocity V1 of the ions I depends on the bias voltage, halving the temperature of the ions I and doubling the bias voltage may have the same effect.

FIG. 10 shows a ratio of the ions I bombarding a bottom H_B of the etched structure on the wafer substrate W to a bias voltage, plotted according to the temperature of the ions I.

From this graphical representation, it can be seen that the ratio of ions I bombarding to the bottom H_B (Ion ratio bombard to bottom (%)) increases as the bias voltage (NSG Voltage (V)) increases. For example, it can be seen that when the temperature of the ions I is 1000K, increasing the bias voltage by 2000V and decreasing the temperature of the ions I by 100K show the same result of the ratio of the ions I bombarding to the bottom H_B, which is about 65%.

In addition, it can be seen that as the temperature of the ions I decreases, the ratio of the ions I bombarding to the bottom H_B increases. In contrast, it can be seen that the graph showing the ratio of the ions I bombarding to the bottom H_B gradually moves upward as the temperature of the ions I increases.

Increasing the bias voltage may cause damage problems such as changes in the hardware design of the plasma etching apparatus, physical limitations, arcing, etc. Therefore, the plasma etching apparatus according to some aspects may lower the temperature of the ions I through a decrease in the temperature of the process gas, thereby increasing the straightness of the ion I. In addition, lowering the temperature of the ion I can provide a similar effect as increasing the bias voltage.

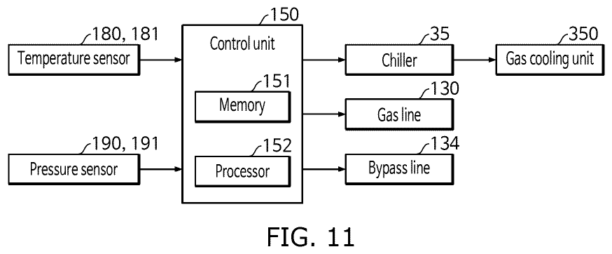

Hereinbelow, a method for controlling the temperature of the process gas of the plasma etching apparatus according to some aspects will be described with reference to FIGS. 11 to 15 according to embodiments of the present disclosure.

FIG. 11 is a block diagram illustrating a configuration of a plasma etching apparatus for controlling a temperature of a process gas according to some aspects.

Referring to FIG. 11, in an embodiment the plasma etching apparatus may include the temperature sensors 180 and 181, the pressure sensors 190 and 191, the control unit 150, the chiller 35, the gas cooling unit 350, the gas line 130, and the bypass line 134.

In an embodiment, the temperature sensors 180 and 181 may include the first temperature sensor 180 that measures the temperature of the process gas flowing inside the gas line 130, and the second temperature sensor 181 that measures the temperature of the process gas flowing inside the gas flow path of the gas cooling unit 350.

The temperature of the process gas measured by the temperature sensors 180 and 181 may be sent to the control unit 150. The control unit 150 may adjust the temperature or flow rate of the coolant flowing through the cooling flow path, based on the temperature of the process gas measured by the temperature sensors 180 and 181. For example, in an embodiment the control unit 150 may control the chiller 35 to adjust the temperature or flow rate of the coolant.

In an embodiment, the pressure sensors 190 and 191 may include the first pressure sensor 190 that measures the pressure of the process gas flowing inside the gas line 130, and the second pressure sensor 191 that measures the pressure of the process gas flowing inside the gas flow path inside the gas cooling unit 350.

The temperature of the process gas measured by the pressure sensors 190 and 191 may be sent to the control unit 150. The control unit 150 may control the chiller 35 to prevent liquefaction of the process gas, based on the pressure of the process gas measured by the pressure sensors 190 and 191. For example, in an embodiment the control unit 150 may control the chiller 35 to adjust the temperature or flow rate of the coolant flowing through the cooling flow path.

In an embodiment, the control unit 150 may control the gas line 130 or the bypass line 134 to be selectively open and closed based on the temperature and/or pressure of the process gas measured by the temperature sensors 180 and 181 and/or the pressure sensors 190 and 191. For example, the control unit 150 may cause a valve provided on the gas line 130 or the bypass line 134 to be open and closed.

In an aspect described below, when the control unit 150 controls a component of the plasma etching apparatus, it may include all embodiments of directly transmitting a control signal to the component, transmitting a control signal to a separate driving device to drive the component, and transmitting a control signal to another intervening component necessary to control the component.

The control unit 150 may include a memory 151 that stores a program and various types of data for executing the operations already described above or to be described below, and a processor 152 that processes data by executing the program stored in the memory 151.

In an embodiment, the memory 151 may include at least one of a volatile memory such as a static random access memory (SRAM), a dynamic random access memory (DRAM), etc., and a nonvolatile memory such as a flash memory, a read only memory (ROM), an erasable programmable read only memory (EPROM), an electrically erasable programmable read only memory (EPROM), etc.

The nonvolatile memory may operate as an auxiliary memory of the volatile memory, and may maintain stored data even if power of the plasma etching apparatus is turned off. For example, in an embodiment the nonvolatile memory may store control programs and control data for controlling the operation of the plasma etching apparatus or the operation of the gas cooling device.

Unlike nonvolatile memory, the volatile memory may lose stored data if power of the plasma etching apparatus is turned off. In an embodiment, the volatile memory may load a control program and control data from the nonvolatile memory and temporarily store the control program and control data, temporarily store an input setting value or control command, or temporarily store a control signal, etc. output from the processor 152.

The processor 152 may process data or output a control signal according to the program stored in the memory 151. For example, in an embodiment the processor 152 may process data or output a control signal according to the program stored in the memory 151 and including instructions for executing the method for controlling the temperature of the process gas described above with reference to FIGS. 12 to 15.

The processor 152 and the memory 151 may be provided in a single configuration or may be provided in a plurality of configurations according to their capacities. In addition, the processor 152 and the memory 151 may be physically separated or may be provided as a single chip.

Hereinafter, the method for controlling the temperature of the process gas executed by the control unit 150 or the processor 152 will be described in detail.

FIGS. 12 to 15 are flowcharts provided to explain a method for controlling the temperature of the process gas of the gas cooling device according to some aspects. Referring to FIG. 12, the process gas may be supplied from the gas box to the gas line, at block S110. For example, the process gas may flow to the gas line and/or the bypass line connected to the gas box.

The first temperature sensor may measure the temperature of the process gas flowing inside the gas line, at block S120. The first temperature sensor may transmit the measured temperature of the process gas to the control unit.

In an embodiment, the control unit may compare the temperature of the process gas measured by the first temperature sensor with a reference temperature, at block S130. For example, the reference temperature may be preset according to a process of the plasma etching apparatus. For example, in an embodiment the reference temperature may be about 40° C. However, embodiments of the present disclosure are not necessarily limited thereto and the reference temperature may be set differently, such as according to the process or the type of the process gas.

If the measured temperature of the process gas is greater than or equal to the reference temperature, the control unit may supply the process gas to the gas cooling device, at block S140. However, embodiments of the present disclosure are not necessarily limited thereto. For example, in some embodiments only if the measured temperature of the process gas is greater than the reference temperature may the control unit supply the process gas to the gas cooling device, at block S140. For example, in an embodiment the control unit may cause the valve provided in the gas line to open and cause the valve provided in the bypass line to be closed such that the process gas is supplied to the gas cooling device.

If the measured temperature of the process gas is lower than the reference temperature, the control unit may supply the process gas to the bypass line, at block S150. Since it is not necessary to cool the process gas any more if the temperature of the process gas is lower than the reference temperature, the control unit may directly supply the process gas to the chamber through the bypass line.

The control unit may supply the process gas discharged from the gas cooling device into the chamber through the outlet line or into the chamber through the bypass line, at block S160. For example, in an embodiment the control unit may control the gas line or the bypass line to be selectively open and closed based on the temperature of the process gas measured by the first

The control unit may compare the temperature of the process gas with the reference temperature to determine whether the process gas needs to be cooled in the gas cooling device. The control unit may supply the process gas to the gas cooling device if it is determined that the process gas should be cooled in the gas cooling device, and supply the process gas through the bypass line if it is determined that the process gas does not need to be cooled. However, embodiments of the present disclosure are not necessarily limited thereto. For example, in some embodiments, even if the temperature of the process gas is lower than the reference temperature, the process gas may not be supplied to the bypass line, but may be supplied to the gas cooling device to be further cooled to a lower temperature.

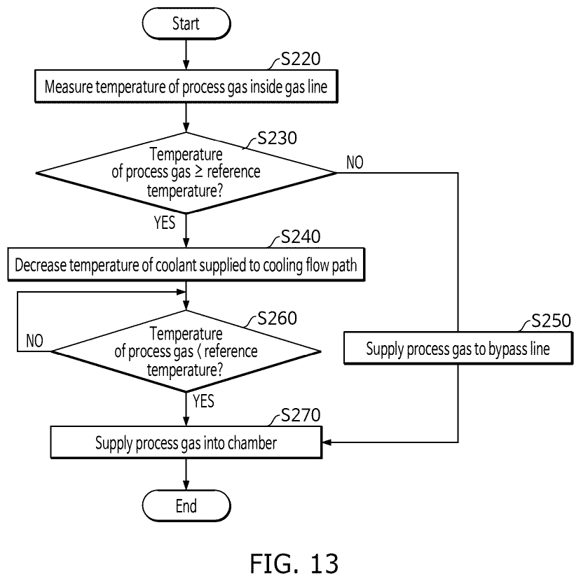

Referring to FIG. 13, the first temperature sensor may measure the temperature of the process gas flowing inside the gas line, at block S220. The first temperature sensor may transmit the measured temperature of the process gas to the control unit.

The control unit may compare the temperature of the process gas measured by the first temperature sensor with a reference temperature, at block S230. In an embodiment, the reference temperature may be adjusted according to a process of the plasma etching apparatus. For example, in an embodiment the reference temperature may be about 40° C. However, embodiments of the present disclosure are not necessarily limited thereto and the reference temperature may be set differently according to the process gas or the type of the process.

In an embodiment in which the measured temperature of the process gas is greater than the reference temperature, the control unit may lower the temperature of the cooling gas supplied to the cooling flow path, at block S240. If the measured temperature of the process gas is greater than the reference temperature, the control unit may control the chiller to lower the temperature of the coolant supplied to the cooling flow path. For example, in an embodiment the chiller may cool the temperature of the coolant to be less than or equal to about 40 degrees Celsius. The coolant may be supplied to the cooling flow path and cool the process gas flowing through the gas flow path.

In an embodiment in which the temperature of the process gas is lower than the reference temperature, the control unit may supply the process gas to the bypass line, at block S250. In an embodiment, since it is not necessary to cool the process gas any more if the temperature of the process gas is lower than the reference temperature, the control unit may directly supply the process gas to the chamber through the bypass line.

The second temperature sensor may measure the temperature of the process gas cooled by the gas cooling device. The second temperature sensor may measure the temperature of the process gas flowing into the gas flow path of the gas cooling device. The temperature of the process gas measured by the second temperature sensor may be transmitted to the control unit. The control unit may compare the temperature of the process gas measured by the second temperature sensor with the reference temperature, at block S260.

In an embodiment in which the temperature of the process gas measured by the second temperature sensor is lower than the reference temperature, the process gas may be supplied into the chamber, at block S270. For example, the process gas may be supplied from the gas cooling device to the chamber through the outlet line.

In an embodiment in which the temperature of the process gas measured by the second temperature sensor is less than or equal to the reference temperature, the control unit may close the flow path such that the process gas does not flow out to the outlet line. For example, the process gas may be further cooled while trapped in the gas flow path. If the temperature of the process gas is cooled below the reference temperature, the process gas may be supplied into the chamber.

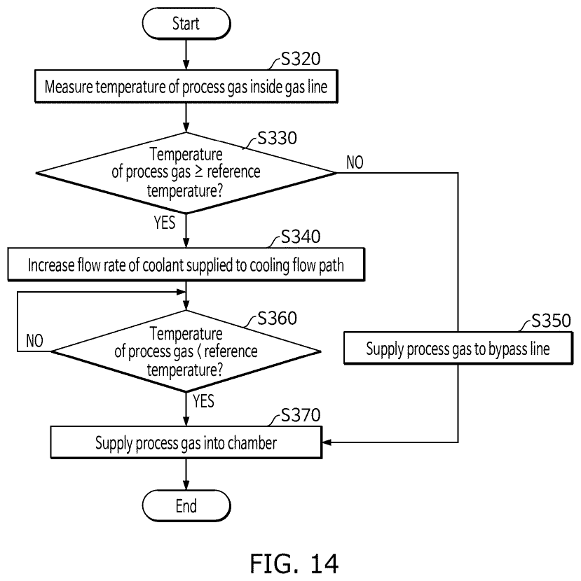

Referring to FIG. 14, the first temperature sensor may measure the temperature of the process gas flowing inside the gas line, at block S320.

The control unit may compare the temperature of the process gas measured by the first temperature sensor with a reference temperature, at block S330. In an embodiment the reference temperature may be adjusted according to a process of the plasma etching apparatus. For example, in an embodiment the reference temperature may be about 40° C. However, embodiments of the present disclosure are not necessarily limited thereto and the reference temperature may be set differently, such as according to the process gas or the type of the process.

In an embodiment, instead of lowering the temperature of the cooling gas supplied to the cooling flow path, the control unit may increase the flow rate of the cooling gas, at block S340. By increasing the flow rate of the cooling gas, the efficiency of heat exchange between the cooling gas and the process gas may be increased. For example, the process gas may be cooled faster.

If the temperature of the process gas is lower than the reference temperature, the control unit may supply the process gas to the bypass line, at block S350. Since it is not necessary to cool the process gas any more if the temperature of the process gas is lower than the reference temperature, the control unit may directly supply the process gas to the chamber through the bypass line.

The control unit may compare the temperature of the process gas measured by the second temperature sensor with the reference temperature, at block S360. In an embodiment in which the temperature of the process gas measured by the second temperature sensor is lower than the reference temperature, the process gas may be supplied into the chamber, at block S370. For example, the process gas may be supplied from the gas cooling device to the chamber through the outlet line.

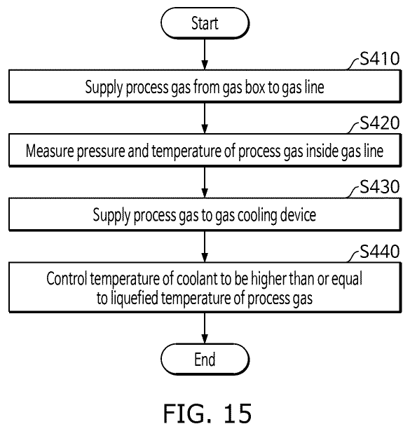

Referring to FIG. 15, the process gas may be supplied from the gas box to the gas line, at block S410.

In an embodiment, the pressure sensor may measure the pressure of the process gas inside the gas line, and the temperature sensor may measure the temperature of the process gas inside the gas line, at S420. The pressure of the process gas measured by the pressure sensor and the temperature of the process gas measured by the temperature sensor may be transmitted to the control unit. The control unit may control the temperature of the coolant based on the pressure of the process gas measured by the pressure sensor and the temperature of the process gas measured by the temperature sensor.

The control unit may supply the process gas to the gas cooling device, at block S430. The process gas may be cooled inside the gas cooling device. For example, in an embodiment the process gas may be cooled while exchanging heat with the coolant inside the gas cooling device. If the temperature of the process gas falls below the liquefaction point, liquefaction may occur. Thus, the process gas may become a liquid if the temperature of the process gas falls below the liquefaction point. The control unit may control the temperature of the process gas not to fall below the liquefaction point to prevent the process gas from being liquefied.

The control unit may control the temperature of the cooling gas so that it is maintained to be greater than or equal to the liquefaction temperature of the process gas, at block S440. The control unit may control the chiller to maintain the temperature of the cooling gas greater than or equal to the liquefaction temperature of the process gas. The chiller may supply a coolant at or above the liquefaction temperature of the process gas. In an embodiment, the control unit may control the chiller such that the temperature of the coolant supplied to the cooling flow path is greater than the liquefaction temperature of the process gas calculated based on the measured pressure of the process gas.

The liquefaction temperature of the process gas may vary depending on the pressure of the process gas. For example, the liquefaction temperature or vapor pressure data according to the pressure of the process gas may be stored in the memory. For example, in an embodiment in which the process gas is ClF₃ and the pressure of the process gas is 402 Torr, the liquefaction temperature of ClF₃ may be 20° C. Accordingly, the control unit may maintain the temperature of the coolant greater than or equal to 20° C. to prevent the process gas from falling below the liquefaction temperature of ClF₃. If other types of process gases are used, the pressure and temperature of the process gasses may be managed by using the vapor pressure data of the corresponding process gasses stored in the memory.

Certain non-limiting embodiments of the present disclosure have been described above for purposes of illustration only, and those skilled in the art with ordinary knowledge of the present disclosure will be able to make various modifications, changes and additions within the spirit and scope of the present disclosure, and such modifications, changes and additions should be construed to be included in the scope of the present disclosure.

It should be understood that those of ordinary skill in the art to which the present disclosure pertains can make various substitutions, modifications and changes without departing from the technical spirit of the present disclosure, and thus, the present disclosure is not limited by the aspects described above and the accompanying drawings.

1. A plasma etching apparatus, comprising:
a chamber receiving a wafer substrate, the wafer substrate is etched inside the chamber;
a gas supply device including a gas box storing a process gas and a gas line transferring the process gas from the gas box to the chamber;
a plasma generator generating a plasma from the process gas inside the chamber; and
a gas cooling device disposed outside the chamber and cooling the process gas supplied from the gas box to the chamber,
wherein the gas line includes an inlet line supplying the process gas from the gas box to the gas cooling device to cool the process gas, and an outlet line supplying the cooled process gas from the gas cooling device to the chamber.

2. The plasma etching apparatus according to claim 1, wherein the gas cooling device includes:
a gas case connected to the gas line, the gas case including a gas flow path that the process gas flows therethrough; and
a cooling case coupled to one side of the gas case, the cooling case including a cooling flow path that a coolant flows therethrough for heat exchange with the process gas flowing in the gas flow path.

3. The plasma etching apparatus according to claim 2, wherein the gas flow path has a shape that is repeatedly bent inside of the gas case.

4. The plasma etching apparatus according to claim 2, further comprising a support frame including a base portion supporting the gas box and a support portion extending along the gas line,
wherein the gas cooling device includes a cabinet accommodating the gas case and the cooling case therein, the cabinet is coupled to the support portion.

5. The plasma etching apparatus according to claim 2, further comprising a chiller supplying the coolant to the cooling flow path.

6. The plasma etching apparatus according to claim 5, wherein the chiller cools the coolant to a temperature less than or equal to about 40 degrees Celsius.

7. The plasma etching apparatus according to claim 5, wherein the gas cooling device further includes:
a temperature sensor measuring a temperature of the process gas flowing into the gas flow path; and
a control unit adjusting a temperature or a flow rate of the coolant flowing through the cooling flow path based on the temperature of the process gas measured by the temperature sensor.

8. The plasma etching apparatus according to claim 7, wherein, if the measured temperature of the process gas is greater than or equal to a reference temperature, the control unit controls the chiller to decrease the temperature or increases the flow rate of the coolant supplied to the cooling flow path.

9. The plasma etching apparatus according to claim 7, wherein the gas cooling device further includes:
a pressure sensor measuring a pressure of the process gas flowing into the gas flow path; and
a control unit controlling a temperature of the coolant flowing through the cooling flow path based on the pressure of the process gas measured by the pressure sensor and the temperature of the process gas measured by the temperature sensor.

10. The plasma etching apparatus according to claim 9, wherein the control unit controls the chiller such that a temperature of the coolant supplied to the cooling flow path is greater than a liquefaction temperature of the process gas calculated based on the measured pressure of the process gas.

11. The plasma etching apparatus according to claim 1, wherein the gas supply device includes a bypass line directly connecting the gas box and the chamber from outside the gas cooling device.

12. The plasma etching apparatus according to claim 11, further comprising:
a temperature sensor measuring a temperature of the process gas flowing inside the gas line; and
a control unit controlling the gas line or the bypass line to be selectively opened and closed based on the temperature of the process gas measured by the temperature sensor.

13. The plasma etching apparatus according to claim 1, wherein:
the gas supply device further includes a first gas injection unit disposed above the wafer substrate, and a second gas injection unit disposed on a sidewall of the chamber, and
the gas line is connected to the first gas injection unit and the second gas injection unit.

14. A plasma etching apparatus, comprising:
a chamber for a plasma etching process;
an electrostatic chuck fixing a wafer substrate in the chamber to etch the wafer substrate;
a gas supply device including a gas box storing a process gas and a gas line supplying the process gas from the gas box into the chamber;
a plasma generator generating a plasma from the process gas inside the chamber;
a gas cooling device coupled to the gas line from outside the chamber, the gas cooling device including a gas flow path that the process gas passes through and a cooling flow path that a coolant passes through; and
a chiller supplying the coolant to the cooling flow path to cool the process gas passing through the gas flow path, wherein
the gas cooling device further includes:
a temperature sensor measuring a temperature of the process gas flowing inside the gas line or the gas flow path; and
a control unit controlling the chiller to adjust a temperature of the coolant based on the temperature of the process gas measured by the temperature sensor.

15. The plasma etching apparatus according to claim 14, wherein, if the temperature of the process gas flowing inside the gas flow path measured by the temperature sensor is greater than or equal to a reference temperature, the control unit controls the chiller to increase the temperature or a flow rate of the coolant supplied to the cooling flow path.

16. The plasma etching apparatus according to claim 14, wherein the gas cooling device further includes a pressure sensor measuring a pressure of the process gas flowing into the gas flow path, wherein
the control unit controls the temperature or a flow rate of the coolant flowing through the cooling flow path based on the pressure of the process gas measured by the pressure sensor.

17. The plasma etching apparatus according to claim 16, wherein the control unit controls the chiller such that a temperature of the coolant supplied to the cooling flow path is greater than a liquefaction temperature of the process gas calculated based on the measured pressure of the process gas.

18. The plasma etching apparatus according to claim 14, wherein:
the gas supply device further includes a bypass line bypassing the gas cooling device and directly connecting the gas box and the chamber to each other; and
the control unit controls the gas line or the bypass line to be selectively opened and closed based on the temperature of the process gas flowing inside the gas line measured by the temperature sensor.

19. The plasma etching apparatus according to claim 14, wherein the gas line includes an inlet line located upstream of the gas cooling device and an outlet line located downstream of the gas cooling device.

20. A plasma etching apparatus, comprising:
a chamber for a plasma etching process;
a support having an electrostatic chuck fixing a wafer substrate inside the chamber;
a gas box storing a process gas;
a gas injection unit injecting the process gas into the chamber, the gas injection unit including a first gas injection unit disposed above the wafer substrate, and a second gas injection unit disposed on a sidewall of the chamber;
an inductively coupled plasma generator generating a plasma from the process gas injected by the gas injection unit;
a gas line connected to supply the process gas from the gas box into the chamber;
a bypass line directly connecting the gas box and the chamber to each other;
a gas cooling device including a gas flow path that the process gas flowing through the gas line passes through, the gas cooling device is disposed outside the chamber;
a chiller including a first channel supplying a coolant to the wafer substrate and a second channel supplying the coolant to the gas cooling device;
a temperature sensor disposed on the gas line and the gas flow path, the temperature sensor measuring a temperature of the process gas;
a pressure sensor disposed on the gas line and the gas flow path, the pressure sensor measuring a pressure of the process gas; and
a control unit that controls the chiller based on the temperature of the process gas measured by the temperature sensor or the pressure of the process gas measured by the pressure sensor.
